(19) United States
(12) Patent Application Publication
(10) Pub. No.: US 2022/0173149 A1
(43) Pub. Date: Jun. 2, 2022

(54) BEAM IMAGING AND PROFILING DEVICE

(71) Applicant: Star Tech Instruments, Inc., New Fairfield, CT (US)

(72) Inventors: William C. Fricke, New Fairfield, CT (US); Mike Ganopoulos, Shelton, CT (US); Clifford A. Martin, Ithaca, NY (US); John K. Wilson, Wilton, CT (US)

(21) Appl. No.: 17/540,418

(22) Filed: Dec. 2, 2021

Related U.S. Application Data
(60) Provisional application No. 63/120,393, filed on Dec. 2, 2020.

(51) Int. Cl. H01L 27/146; G01J 1/58; G02B 13/14

(52) U.S. Cl. CPC H01L 27/14625; G02B 13/143; G01J 1/58; H01L 27/14676

(57) ABSTRACT

Exemplary aspects of the present invention are directed to an imaging sensor system for beams in the 1-200 nm spectral regions. The system may include a downconverter for converting the beam to visible light, optical filter elements, and relay optics for directing the visible light to the imaging detector. The relay optics convey the image and/or optical beam profile intensity to a 2-D imaging array such as CMOS, CCD (or other imaging detector device). The system can be used in a vacuum or in ambient non-vacuum conditions which may include a purged environment.

### CROSS-REFERENCE TO RELATED APPLICATIONS

This application claims priority to U.S. Provisional Appl. No. 63/120,393 filed Dec. 2, 2020, which is hereby incorporated by reference in its entirety.

### BACKGROUND OF THE INVENTION

### 1. Field of the Invention

The present invention is directed to a beam imaging and profiling device, and more particularly to an imaging sensor for the 1 to 200 nm spectral regions.

### 2. Related Art

New technological advances require new solutions for high resolution imaging in the VUV, XUV, X-ray and soft X-ray regions (1-200 nm). These developments have necessitated unique solutions for analyzers and diagnostic tools. The applications include, but are not limited to: microlithography, microbiology, medical and diagnostic metrology. These new applications require increased resolution and push the development of new measurement capabilities or the deep UV and X-ray regions. Existing imaging systems have serious limitations. Degradation of the imaging and the optical elements due to exposure by the beam can result in damage and change in responsivity. This results in inaccurate readings over time and requires re-calibration or replacement of the sensor and/or the optical members.

Various related art includes U.S. Pat. No. 4,731,811 issued Mar. 15, 1988 and entitled Narrow Spectral Bandwidth, UV Solar Blind Detector, U.S. Pat. No. 4,885,471 issued Dec. 5, 1989 and entitled Ultraviolet Radiometer, U.S. Pat. No. 6,340,820 issued Jan. 22, 2002 and entitled Near-Visible Light Detection Method and Apparatus, and U.S. Appl. Publ. No. 2005/0254122 published Nov. 17, 2005 and entitled Apparatus for Viewing and Analyzing Ultraviolet Beams, all of which are hereby incorporated by reference in their entireties.

What is needed is a sensor that is not degraded by VUV, XUV, X-ray, Soft X-ray exposure, and therefore results in much better long-term accuracy without the need for frequent sensor re-calibrations or replacements. Therefore, there is a need for an apparatus for sensing beams where the performance does not change or decline over time.

### SUMMARY OF THE INVENTION

In accordance with the present invention, the foregoing objects and advantages have been readily attained.

The present invention is directed to a sensor that is not degraded by VUV, XUV, X-ray, Soft X-ray exposure, and therefore results in an improved long-term accuracy without the need for frequent sensor recalibrations or replacements.

According to an exemplary aspect of the invention, an imaging sensor for the VUV, XUV, X-ray wavelength(s) 1-200 nm may include one or more downconverters for converting the VUV, XUV, X-ray beam to easily detectable light, e.g., visible, infrared or near infrared light, an imaging detector for the detectable light, and relay optics for directing the visible light to the imaging detector(s). The imaging detectors(s) is/are in communication with a computing device for conveying information regarding the intensity profile of the beam to a beam intensity display device.

The invention relates to a highly accurate beam profiling sensor for VUV, XUV, X-ray and soft X-ray beams (collectively referred to hereinafter as beams), which accurately and reliably produces an image and or beam profile information of the beam without performance degradation due to long-term exposure to UV/X-ray radiation. As used herein, the term “beam” refers to any VUV, XUV, X-ray and soft X-ray source.

In accordance with the present invention, the VUV, XUV, soft X-ray and X-ray beam is downconverted to longer wavelength radiation (visible, near-IR, etc., hereinafter collectively referred to as visible light) and relayed to an image sensor and convey this information to the displaying member. In this manner, the image sensing member is not exposed directly to the incident VUV, XUV, X-ray beam and is therefore protected from same.

Exemplary aspects of the present invention are directed to an imaging sensor system for beams in the 1-200 nm spectral regions. The system may include a downconverter for converting the beam to visible light, optical filter elements, and relay optics for directing the visible light to the imaging detector. The relay optics convey the image and/or optical beam profile intensity to a 2-D imaging array such as CMOS, CCD (or other imaging detector device). The system can be used in a vacuum or in ambient non-vacuum conditions which may include a purged environment.

In accordance with an exemplary aspect of the present invention, an image sensor for a beam is provided that may include a downconverter configured to convert the beam to visible or near visible light, an imaging detector configured to sense an intensity of the visible or near visible light, relay optics configured to direct the visible or near visible light to the imaging detector, and one or more additional imaging detectors configured to receive information regarding comparative intensity of the visible or near visible light in multiple channels from the imaging detector.

In accordance with the above and other exemplary aspects of the present invention, the image member may be a silicon detector CCD, CMOS or a sensor that is configured to detect the image in the emission of the resulting energy from the downconverter.

In accordance with the above and other exemplary aspects of the present invention, the intensity profile sensing member may be a silicon detector CCD, CMOS or other sensor that can detect the beam intensity distribution in the emission of the resulting energy from the downconverter.

In accordance with the above and other exemplary aspects of the present invention, the beam may be a VUV, XUV, X-ray or Soft X-ray beam.

In accordance with the above and other exemplary aspects of the present invention, the beam may be in the 1 to 200 nm wavelength.

In accordance with the above and other exemplary aspects of the present invention, the visible light may be in the 380 to 700 nm wavelength.

In accordance with the above and other exemplary aspects of the present invention, the near visible light may be in the 700 to 1,500 nm wavelength.

In accordance with the above and other exemplary aspects of the present invention, the relay optics may include one or more optical fibers.

In accordance with the above and other exemplary aspects of the present invention, the image sensor may also include a vacuum window positioned between the downconverter and the relay optics.

In accordance with the above and other exemplary aspects of the present invention, the image sensor may also include a filter positioned between the vacuum window and the relay optics.

In accordance with the above and other exemplary aspects of the present invention, the image sensor may also include a computer configured to receive a signal from the imaging detector and display the signal as information on an electronic display.

### BRIEF DESCRIPTION OF THE SEVERAL VIEWS OF THE DRAWINGS

For a fuller understanding of the nature and object of the present invention, reference should be had to the following detailed description taken in connection with the accompanying drawings, in which:

FIGS. 1 and 2 show schematic illustrations of exemplary apparatus according to the present invention.

### DETAILED DESCRIPTION OF THE INVENTION

The present invention now will be described more fully hereinafter with reference to the accompanying figures, in which exemplary embodiments of the invention are shown. The invention may, however, be embodied in many different forms and should not be construed as limited to the embodiments set forth herein. Like reference numerals refer to like elements throughout.

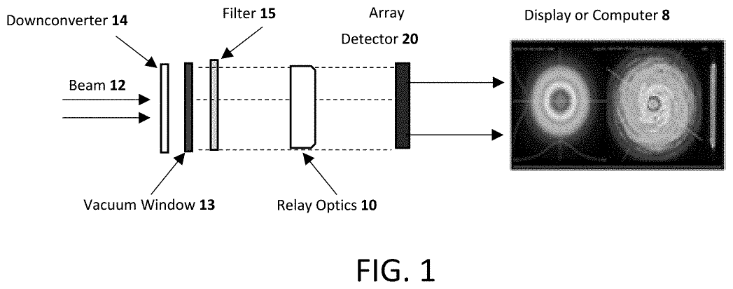

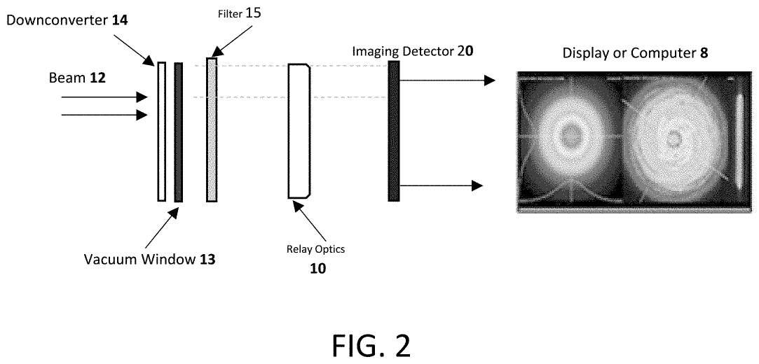

Referring now to FIGS. 1 and 2, therein illustrated are schematics of exemplary image sensors according to an aspect of the present invention. The image sensors are generally configured to receive a beam 12, which may be a VUV, XUV, X-ray, Soft X-ray or the like beam having about a 1 to 200 nm wavelength, down-convert the beam 12 into longer wavelength radiation, for example, visible, near-infrared or infrared light, relay the down-converted beam to an imaging detector 20 (or array detector) and convey the information from the imaging detector 20 to a display device 8, such as a computer. In this manner, the imaging detector 20 is not exposed directly to the incident VUV, XUV, X-ray of Soft X-ray beam, and is therefore protected. The image sensor may include a downconverter 14, which is configured to convert the beam 12 into longer wavelength radiation, such as visible or infrared light. The image sensor may also include a vacuum window 13 positioned so as to receive the longer wavelength radiation from the downconverter 14. The image sensor may further include one or more optical filters 15 and one or more relay optics 10, which may include fiber optics, lenses or other optical transfer devices. The optical filters 15 may be positioned between the downconverter 14 and the relay optics 10, and the relay optics 10 are configured to convey the longer wavelength radiation to the imaging detector 20. The imaging detector 20 may be a CCD, CMOS or other type of imaging array detector that is configured to provide information or feedback to the display device 8.

It is understood that the image sensor in accordance with the present invention advantageously avoids direct incidence of the beam 12 on imaging detector 20, which would cause rapid damage or destruction of the imaging detector 20. Rather, the beam 12 is advantageously converted to longer wavelength radiation and focused onto the imaging detector 20, such that the image intensity profile of the longer wavelength radiation can be detected and correlated to the intensities of the beam 12, so as to advantageously provide accurate, and long-term reliable, information regarding intensity profiles of the beam 12 conveyed to the display device 8.

It should be noted that the relay optics 10, vacuum window 13, downconverter 14, optical filters 15, imaging detector 20 (or array detector) and display device 8 are all devices which themselves are well known to a person of ordinary skill in the art.

The image sensor can be used in numerous industrial, medical or similar procedures where the accurate image details of beams is critical, and the long term degradation of the imaging detector 20 can result in inaccuracies that could be harmful. Specific examples of various applications for the image sensor according the various aspects of the present invention include band specific intensity monitoring in microlithography, microbiology, medical, diagnostic metrology and similar applications.

In accordance with various embodiments of the present invention, certain aspects of the invention may be implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

It will thus be seen that the objects set forth above, among those made apparent from the preceding description, are efficiently attained and, since certain changes may be made in the above article without departing from the scope of this invention, it is intended that all matter contained in this disclosure or shown in the accompanying drawings, shall be interpreted, as illustrative and not in a limiting sense. It is to be understood that all of the present figures, and the accompanying narrative discussions of corresponding embodiments, do not purport to be completely rigorous treatments of the invention under consideration. It is to be understood that the above-described arrangements are only illustrative of the application of the principles of the present invention. Numerous modifications and alternative arrangements may be devised by those skilled in the art without departing from the scope of the present invention.

What is claimed is:

1. An image sensor for a beam, comprising:
a downconverter configured to convert the beam to visible or near visible light;
an imaging detector configured to sense an intensity of the visible or near visible light;
relay optics configured to direct the visible or near visible light to the imaging detector; and
one or more additional imaging detectors configured to receive information regarding comparative intensity of the visible or near visible light in multiple channels from the imaging detector.

2. The image sensor according to claim 1, wherein the image member is a silicon detector CCD, CMOS or a sensor that is configured to detect the image in the emission of the resulting energy from the downconverter.

3. The image sensor according to claim 1, wherein the intensity profile sensing member is a silicon detector CCD, CMOS or other sensor that can detect the beam intensity distribution in the emission of the resulting energy from the downconverter.

4. The image sensor according to claim 1, wherein the beam is a VUV, XUV, X-ray or Soft X-ray beam.

5. The image sensor according to claim 1, wherein the beam is in the 1 to 200 nm wavelength.

6. The image sensor according to claim 1, wherein the visible light is in the 380 to 700 nm wavelength.

7. The image sensor according to claim 1, wherein the near visible light is in the 700 to 1,500 nm wavelength.

8. The image sensor according to claim 1, wherein the relay optics comprise one or more optical fibers.

9. The image sensor according to claim 1, further comprising a vacuum window positioned between the downconverter and the relay optics.

10. The image sensor according to claim 9, further comprising a filter positioned between the vacuum window and the relay optics.

11. The image sensor according to claim 1, further comprising a computer configured to receive a signal from the imaging detector and display the signal as information on an electronic display.
